(19) United States
(12) Patent Application Publication
(10) Pub. No.: US 2002/0076836 A1
(43) Pub. Date: Jun. 20, 2002

(54) Process for manufacturing a ferroelectric capacitor

(75) Inventor: Sebastiano Ravesi, Sant'Agata Li Battiati (IT)

Correspondence Address: SEED INTELLECTUAL PROPERTY LAW GROUP PLLC, 701 FIFTH AVE, SUITE 6300, SEATTLE, WA, 98104-7092, US

(73) Assignee: STMicroelectronics S.r.l., Agrate Brianza (IT)

(21) Appl. No.: 09/874,890

(22) Filed: Jun. 4, 2001

(30) Foreign Application Priority Data
Jun. 9, 2000 (IT) TO2000A 000565

(51) Int. Cl. H01L 21/00; H01L 21/8242

(52) U.S. Cl. 438/3; 438/240; 438/253

(57) ABSTRACT

A process for manufacturing a ferroelectric capacitor includes the steps of forming a first plate of a noble metal, preferably platinum, above an insulating layer of a wafer; forming a dielectric material layer with ferroelectric properties; and forming a second plate of a noble metal above said dielectric material layer. The first plate and the second plate are formed by electrochemical deposition of a metal.

### TECHNICAL FIELD

The present invention relates to a process for manufacturing a ferroelectric capacitor.

### BACKGROUND OF THE INVENTION

An example of a ferroelectric capacitor obtained by a known fabrication process is illustrated in FIG. 1.

According to the known process, an insulating layer 3 is deposited above a portion of a wafer 1 comprising a substrate 2 of semiconductor material, to ensure that the capacitor is insulated against the substrate.

A first metal layer 5 is then deposited above the insulating layer 3. Subsequently, the first metal layer 5 is defined such as to form a first plate (again indicated as 5 for the sake of clarity) made of noble metal.

A dielectric material layer 6 which has ferroelectric properties and a second metal layer 7 are subsequently deposited above the first plate 5.

The second metal layer 7 is then defined to form a second plate 7 of noble metal.

Finally, the dielectric material layer 6 is defined by a photolithographic process.

Alternatively, a process for manufacturing ferroelectric capacitors is also known, comprising the steps of depositing, in sequence, the first metal layer, the dielectric material layer which has ferroelectric properties, and the second metal layer, and subsequently defining the deposited layers through photolithographic processes, to form the second plate 7 of the capacitor, the dielectric layer 6, and the first plate 5.

According to the prior art, the metal layers forming the first plate 5 and the second plate 7 of the ferroelectric capacitor generally consist of noble metals, preferably platinum or gold. In fact, noble metals do not react in the presence of the oxygen present inside the dielectric material layer 6, and thus they do not lead to deterioration of the dielectric material.

Specifically owing to their low reactivity, it is not possible to use chemical etching for defining the first and the second plates 5, 7 of the capacitor, which thus occurs by physical erosion of the metal layers.

However, the physical erosion is a process which is difficult to control, and therefore the definition of the outline of the plates of the capacitors is imprecise and inaccurate, and provides ferroelectric capacitors which have plates with different dimensions, and thus electrical characteristics which differ from one another.

### SUMMARY OF THE INVENTION

An embodiment of the present invention provides a process which can accurately fabricate ferroelectric capacitors which have plates with consistent, well-controllable dimensions. The process includes the steps of forming a first plate of a noble metal above an insulating layer on a semiconductor substrate, forming a dielectric region with ferroelectric properties above said first plate and forming a second plate of a noble metal above the dielectric region wherein at least one of the steps of forming first and second plates includes the step of electrochemical deposition of a metal.

### BRIEF DESCRIPTION OF THE DRAWINGS

In order to assist understanding of the present invention, a preferred embodiment is now described, purely by way of non-limiting example, and with reference to the attached drawings, in which:

FIG. 1 shows a cross-section through a silicon wafer of a ferroelectric capacitor according to the known art;

FIG. 2 shows a cross-section through a silicon wafer in a first step of a process according to the invention;

FIGS. 3 to 9 show cross-sections similar to FIG. 2, in successive fabrication steps; and

FIG. 10 shows a cross-section through a silicon wafer, in a final step of a process according to the invention.

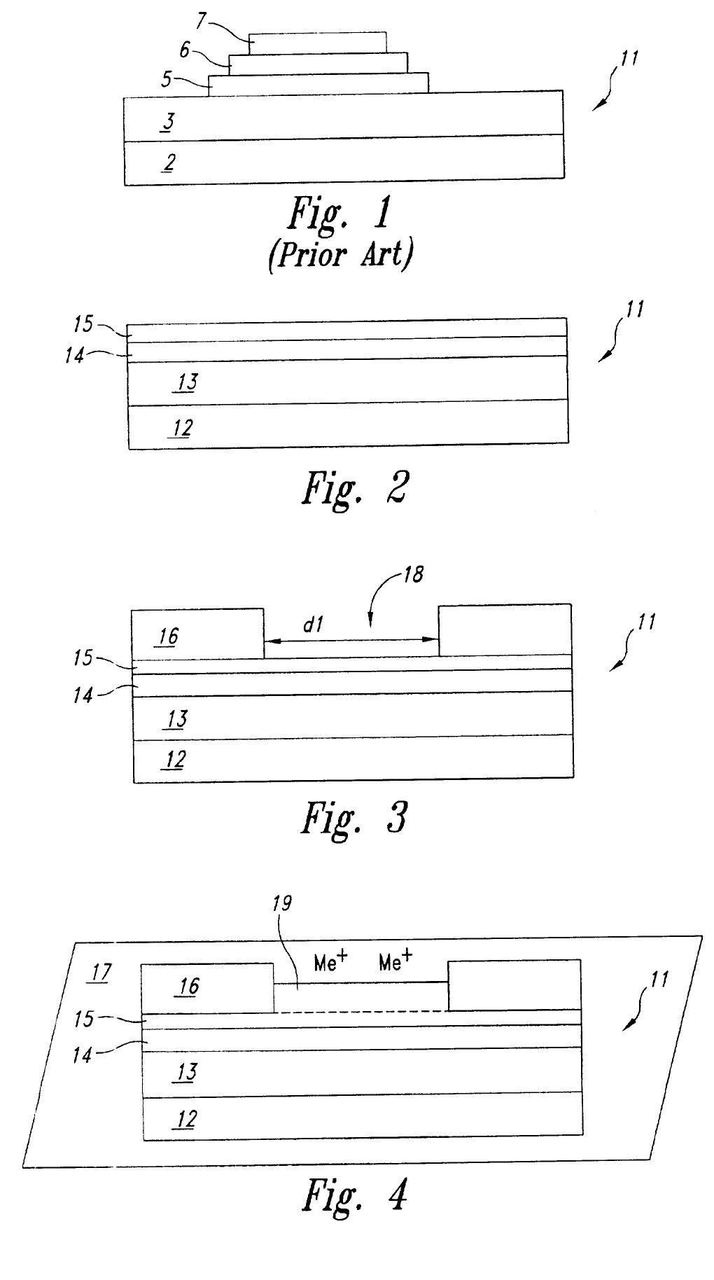

### DETAILED DESCRIPTION OF THE INVENTION

FIG. 2 illustrates schematically a wafer 11 comprising a substrate 12 of monocrystalline silicon, superimposed by an insulating layer 13.

An adhesive metal layer 14 is deposited on the insulating layer 13, to assist the adhesion between the insulating layer 13 and successive layers. A material is therefore used which can form a bond with the insulating layer 13, but which at the same time permits formation of intermetal bonds with the layers deposited successively. For example titanium or a compound based on titanium can be used.

A first seed layer 15 is then deposited, of a thin layer of noble metal, preferably platinum, but also, for example, gold or another metal which does not react with oxygen.

Above the first seed layer 15, a first protective resist mask 16 is formed and has a first aperture 18 with a width d1, as illustrated in FIG. 3, where the first plate of the ferroelectric capacitor will be formed.

Subsequently, the wafer 11 is immersed in a solution which contains cations of the noble metal of the same type as the first seed layer 15, inside an electrochemical cell 17, known, and thus illustrated only schematically in FIG. 4.

Current is then passed through the first seed layer 15, defining the cathode of the electrochemical cell, and a reduction reaction:

Me⁺+e⁻→Me

takes place, wherein Me is the noble metal forming the first seed layer 15, and Me⁺ is the corresponding cation in solution.

Thereby, metal material is deposited, and a first plate layer 19 of noble metal is formed at the first aperture 18 of the first protective mask 16 (FIG. 4).

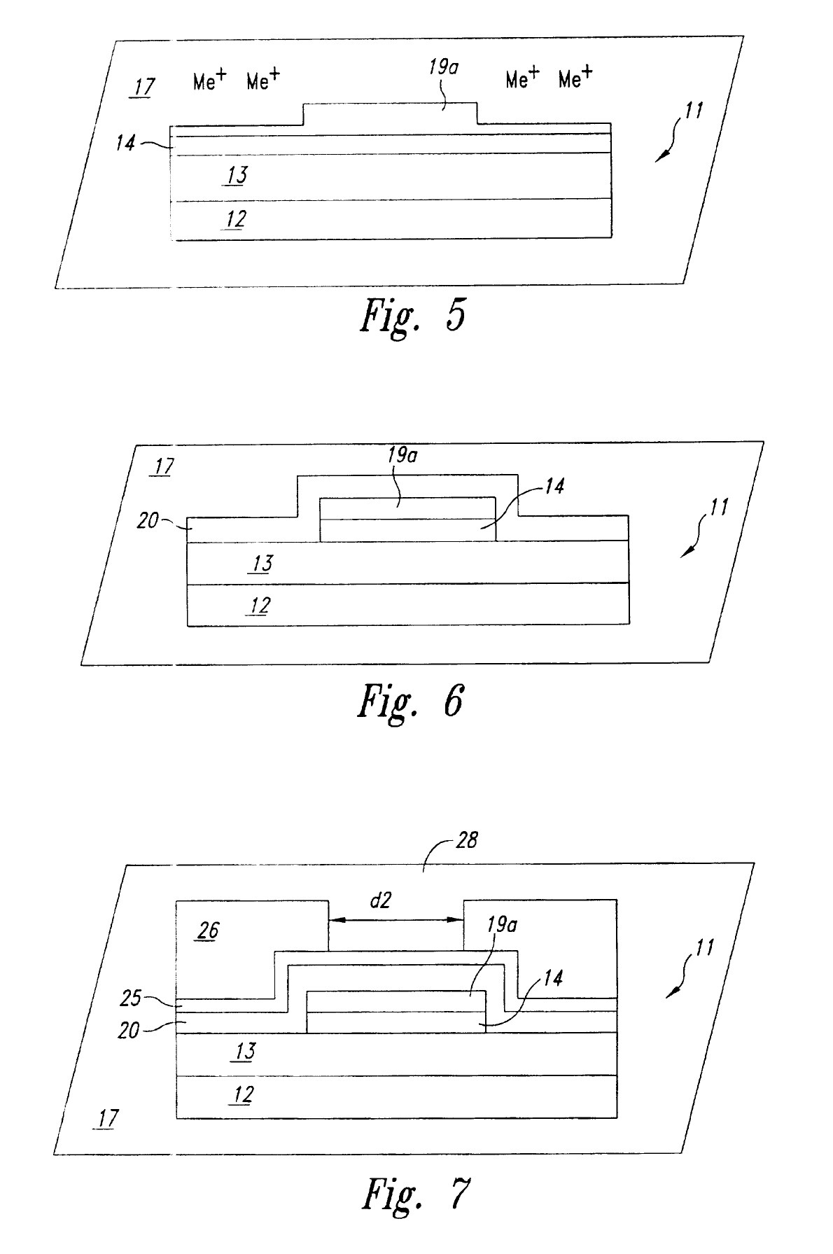

Subsequently, as illustrated in FIG. 5, the first protective mask 16 is removed, biasing is reversed inside the electrochemical cells, and current is supplied for carrying out the reverse reaction:

Me→Me⁺+e⁻.

Thereby, the metal forming the first seed layer 15 is dissolved and put into solution. Since this reaction is not selective, during this step some of the metal which forms the first plate layer 19 is also put into solution and the thickness of the first plate layer 19 is thus reduced.

Thereby a first plate 19a of the ferroelectric capacitor is defined. In view of the high controllability of the electrochemical growth and dissolving process, by calculating the times necessary for carrying out these processes, it is possible to accurately control the thickness of the first plate 19a.

Subsequently, the adhesive layer 14 is removed by chemical etching, apart from in the areas where it is covered by the first plate 19a.

A dielectric layer 20 with ferroelectric characteristics is then deposited on the entire surface of the wafer 11, as shown in FIG. 6.

Above the dielectric layer 20 a second seed layer 25 of a thin layer of noble metal, similar to the first seed layer 15, is then deposited.

Subsequently, as shown in FIG. 7, a second protective mask 26 is provided, which has a second aperture 28 where the second plate of the ferroelectric capacitor will be formed. The second aperture 28 generally has a width d2 which is smaller than the first aperture 18.

Current is then passed through the second seed layer 25, that forms the cathode of the electrochemical cell, and causes the reduction reaction:

Me⁺+e⁻→Me.

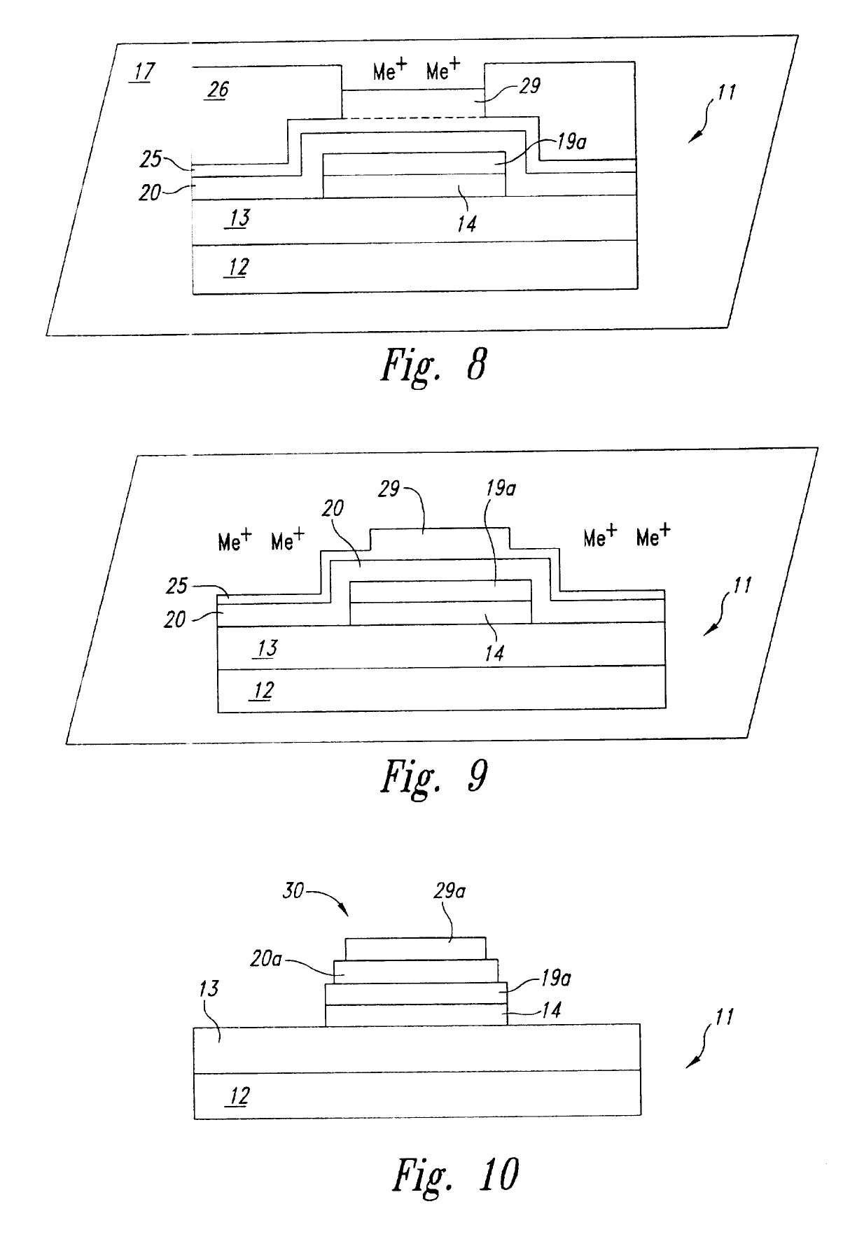

Thereby, metal material is deposited, and a second noble metal plate layer 29 is formed, at the second aperture 28 of the second protective mask 26, as shown in FIG. 8.

Subsequently, and as illustrated in FIG. 9, the second protective mask 26 is removed, biasing inside the electrochemical cell is reversed, and current is supplied such as to make the reverse reaction:

Me→Me⁺+e⁻

take place once more.

Thereby the metal forming the second seed layer 25 dissolves and is put into solution. Since this reaction is not selective, during this step some of the metal which forms the second plate layer 29 is also put into solution, and the thickness of the second plate layer 29 is thus reduced. In this case also, it is possible to control the process steps such as to accurately control the final thickness required.

Thus, a second plate 29a of the ferroelectric capacitor is defined, as shown in FIG. 10.

Finally, through a photolithographic process, the dielectric layer 20 is removed from the entire wafer, except from below the second plate 29a, and forms the dielectric region 20a.

Thereby a ferroelectric capacitor is obtained, indicated at 30 in FIG. 10, and comprises a first noble metal plate 19a, a dielectric region 20a with ferroelectric properties, and a second noble metal plate 29a. Subsequently, the ferroelectric capacitor 30 thus obtained is connected to the integrated circuit in a per se known manner, not described in detail.

The advantages of the process for manufacturing the described electronic devices are apparent from the foregoing description. In particular, the fact is emphasised that the process makes it possible to obtain ferroelectric capacitors which have plate dimensions which are accurate and constant throughout the batch, and have neat, smooth outlines, and reproduce exactly the geometry required.

In addition, the process described is particularly advantageous since it permits fine modulability of the thickness of the plates.

The process is easy to implement, and, since the purity of the metal deposited electrochemically is particularly high, high-quality ferroelectric capacitors are obtained.

Finally, it is apparent that many modifications and variants can be made to the manufacturing process described and illustrated here, all of which come within the scope of the invention, as defined in the attached claims.

For example, it is possible to deposit the first metal seed layer 15 directly onto the insulating layer 13, without interposing the adhesive layer 14.

From the foregoing it will be appreciated that, although specific embodiments of the invention have been described herein for purposes of illustration, various modifications may be made without deviating from the spirit and scope of the invention. Accordingly, the invention is not limited except as by the appended claims.

We claim:

1. A process for the fabrication of a ferroelectric capacitor, comprising the steps of:
a. forming a first plate of a noble metal;
b. forming a dielectric region with ferroelectric properties, above said first plate; and
c. forming a second plate of a noble metal above said dielectric region,
wherein at least one of said steps of forming a first plate and a second plate comprises the step of electrochemical deposition of a metal.

2. A process according to claim 1, wherein both said steps of forming a first and a second plate comprise the step of electrochemically depositing a metal.

3. A process according to claim 1, wherein said steps of forming a first and a second plate each comprise the step of depositing a seed layer made of noble metal, before said step of electrochemical deposition of a metal.

4. A process according to claim 3, wherein a single noble metal is used for said first and second plates and for said seed layer.

5. A process according to claim 3 wherein said step of electrochemical deposition of a metal comprises the steps of:
placing a semiconductor material wafer in a solution containing cations of said noble metal, inside an electrochemical cell;
biasing said seed layer; and
selectively growing a layer of noble metal.

6. A process according to claim 5, wherein, after said step of selectively growing, the step is carried out of removing said seed layer laterally to said first and second plates.

7. A process according to claim 6, wherein said step of selectively growing comprises the step of passing electric current in a first direction through said seed layer, and in that said step of selectively removing comprises the step of passing electric current in a second direction through said seed layer.

8. A process according to claim 1, wherein at least one of said steps for forming a first and a second plate comprises the step of forming a lateral delimitation mask, that has an aperture, and selectively growing said noble metal inside said aperture.

9. A process according to claim 1, before said step of forming a first plate, the step is carried out of depositing an adhesive layer above a semiconductor material wafer.

10. A process according to claim 9, wherein said adhesive layer comprises titanium.

11. A process according to claim 1, wherein said noble metal is selected between platinum and gold.

12. A process according to claim 1, wherein said plates are formed above a wafer comprising a semiconductor material body and an insulating layer.

13. A method, comprising:
forming a first noble metal layer on a semiconductor substrate;
forming a first protective mask on the first noble metal layer, the first protective mask having an aperture exposing a region of the first noble metal layer;
forming, by electrochemical deposition, a first metallic layer within the aperture of the protective mask, the first metallic layer covering the region of the first noble metal layer;
removing the protective mask; and
removing, by electrochemical dissolution, the first noble metal layer except for the region covered by the first metallic layer.

14. The method of claim 13, further comprising:
forming a dielectric layer on the semiconductor substrate, above the metallic layer;
forming, on the dielectric layer, a second noble metal layer;
forming a second protective mask on the second noble metal layer, the second protective mask having an aperture defining a region of the second noble metal layer;
forming, by electrochemical deposition, a second metallic layer within the aperture of the second protective mask, the second metal layer covering the region of the second noble metal layer;
removing the second protective mask; and
removing, by electrochemical dissolution, the second noble metal layer except for the region of the second noble metal layer covered by the second metallic layer.

15. The method of claim 14 wherein the first and second noble metal layers and the first and second metallic layers are of the same noble metal.

16. The method of claim 13, further comprising:
forming, prior to forming the first noble metal layer, an adhesive metal layer on the semiconductor substrate; and
removing, following removing the first noble metal layer, the adhesive metal layer, except for a portion covered by the first noble metal layer.

17. A capacitor on a semiconductor substrate, comprising:
an adhesive metal layer formed on the substrate;
a first noble metal layer formed on the adhesive metal layer;
a dielectric layer formed on the first noble metal layer; and
a second noble metal layer formed on the dielectric layer.

18. The capacitor of claim 17, further comprising an insulating layer positioned between the adhesive metal layer and the substrate.

19. The capacitor of claim 17, wherein the first noble metal layer and the second noble metal layer are of the same metal, chosen from among gold and platinum.
